(19) United States
(12) Patent Application Publication
(10) Pub. No.: US 2015/0145440 A1
(43) Pub. Date: May 28, 2015

(54) ORGANIC EL PANEL AND METHOD FOR MANUFACTURING LIGHT-EMITTING DEVICE USING THE SAME

(71) Applicant: Shinichi Ishizuka, Kawasaki-shi (JP)

(72) Inventor: Shinichi Ishizuka, Kawasaki-shi (JP)

(73) Assignee: PIONEER CORPORATION, Kawasaki-shi, Kanagawa (JP)

(21) Appl. No.: 14/402,663

(22) PCT Filed: May 22, 2012
(86) PCT No.: PCT/JP2012/063068

§ 371 Date: Nov. 20, 2014

(51) Int. Cl. H05B 33/08; H01L 51/00; H01L 21/66; H01L 51/56

(52) U.S. Cl. CPC H05B 33/0896; H01L 51/56; H01L 51/0031; H01L 22/12; H01L 22/14; H01L 22/20
USPC 315/307; 438/7; 438/15

(57) ABSTRACT

An organic EL panel with less variation in an emission luminance thereof and a method for manufacturing a light-emitting device using the same are provided. The organic EL panel of the present invention includes: a substrate; a light-emitting section of the organic EL panel provided on the substrate; a current supply terminal provided on the substrate for supplying a current to the light-emitting section; and a current density adjusting section electrically connected to the current supply terminal in parallel to the light-emitting section and provided on the substrate. A current density of the light-emitting section is adjusted by processing of the current density adjusting section. Moreover, in the method for manufacturing a light-emitting device according to the present invention, after a light-emitting characteristic is adjusted by processing a post-processing region of the above-described organic EL panel, a light-emitting device including the processed organic EL panel is manufactured.

### TECHNICAL FIELD

The present invention relates to an organic electroluminescent panel (hereinafter referred to as an organic EL panel) and a method for manufacturing a light-emitting device using the same.

### BACKGROUND ART

In order to improve the energy efficiency of an illuminating device, efforts are being made for the research and development of a light source as a substitute for an incandescent bulb or a fluorescent lamp. Recently, a high luminance LED (light-emitting diode), or the like, has been regarded as one of leading candidates and application products thereof have been actually commercialized. Also, the market of lighting using an organic EL panel is being established following such a high luminance LED.

In LED lighting, since a light-emitting element emits light in a narrow region, the light needs to be diffused in some way. In the lighting using an organic EL panel, on the other hand, the organic EL panel itself makes surface emission, thus having an advantage of being able to obtain wide and uniform light. Moreover, the organic EL panel is very thin and a wall surface itself of a room can be therefore functioned as lighting by attaching the organic EL panel to the wall or ceiling thereof, for example. By giving flexibility to an organic EL panel with the use of a flexible substrate made of a flexible plastic, the organic EL panel can be attached to a curved surface.

Organic EL panels have variations in the characteristics of a light-emitting layer due to differences in their manufacturing processes, lots, or the materials of the light-emitting layer. Due to such variations in the characteristics of the light-emitting layer, characteristic variations in an emission luminance (current density−luminance efficiency) are caused in the organic EL panels juxtaposed for lighting of a wide area, for example.

In order to eliminate such emission luminance variations, an adjustment by a drive circuit is required so that the organic EL panels have a constant emission luminance. Moreover, at the time of replacing an organic EL panel, an adjustment needs to be made for an individual organic EL panel since organic EL panels have different emission luminances due to the individual differences thereof. Furthermore, when a light-emitting device is constituted by using a plurality of organic EL panels, emission luminances are different from each other between adjacent organic EL panels if the organic EL panels are connected and driven in series, thereby resulting in a degraded appearance thereof.

For example, Patent Literature 1 discloses that when a light-emitting device is constituted by using a plurality of panels, emission luminance variations in the organic EL panels are suppressed by providing an output detection terminal in the organic EL panel and performing feedback control for controlling a power supply to a light-emitting element on the basis of an output of the output detection terminal.

### CITATION LIST

### Patent Literature

Patent Literature 1: Japanese Patent Application Laid-Open No. 2009-54426

### SUMMARY OF INVENTION

### Technical Problem

According to the invention of Patent Literature 1, however, while it is conceivable that the emission luminance variations of the organic EL panels can be effectively suppressed by controlling power supply to the light-emitting elements so that the outputs of the output detection terminals have the same value, the circuit as a whole becomes complicated due to the formation of a feedback control circuit and the integration of such a control circuit into a drive circuit system of the organic EL panel and the manufacturing cost thereof is thereby increased.

In view of this, the above-described problems can be given as an example of problems to be solved by the invention. It is an object of the present invention to provide a light-emitting device including organic EL panels capable of suppressing emission luminance variations among the organic EL panels while achieving a reduced manufacturing cost with the use of a relatively simple configuration without a control circuit.

### Solution to Problem

An organic EL panel of the invention according to claim 1 includes: a substrate; a light-emitting section of the organic EL panel provided on the substrate; a current supply terminal provided on the substrate for supplying a current to the light-emitting section; and a current density adjusting section electrically connected to the current supply terminal in parallel to the light-emitting section and provided on the substrate. A current density of the light-emitting section is adjusted by processing the current density adjusting section to cause a physical breakage therein.

### BRIEF DESCRIPTION OF DRAWINGS

FIG. 1 is a plan view of an organic EL panel according to an embodiment of the present invention.

FIG. 2 is a cross-sectional view taken along the line A-A in FIG. 1.

FIG. 3 is a cross-sectional view taken along the line B-B in FIG. 1.

FIG. 4 is a circuit diagram of an IC chip constituting part of the organic EL panel in FIG. 1.

FIG. 5 is a circuit diagram of an IC chip constituting part of the organic EL panel in FIG. 1.

FIG. 6 is a circuit diagram of an IC chip constituting part of the organic EL panel in FIG. 1.

FIG. 7 is a perspective view illustrating a case where a current density adjusting section includes a chip component.

FIG. 8 is a plan view illustrating the case where the current density adjusting section includes the chip component.

FIG. 9 is a cross-sectional view illustrating the case where the current density adjusting section includes the chip component.

FIG. 10 is a flow chart of a manufacturing process of an organic EL panel.

FIG. 11 is a flow chart of a manufacturing process of the current density adjusting section.

FIG. 12 is a flow chart of a method for manufacturing an organic EL light-emitting device.

### DESCRIPTION OF EMBODIMENTS

### Embodiments

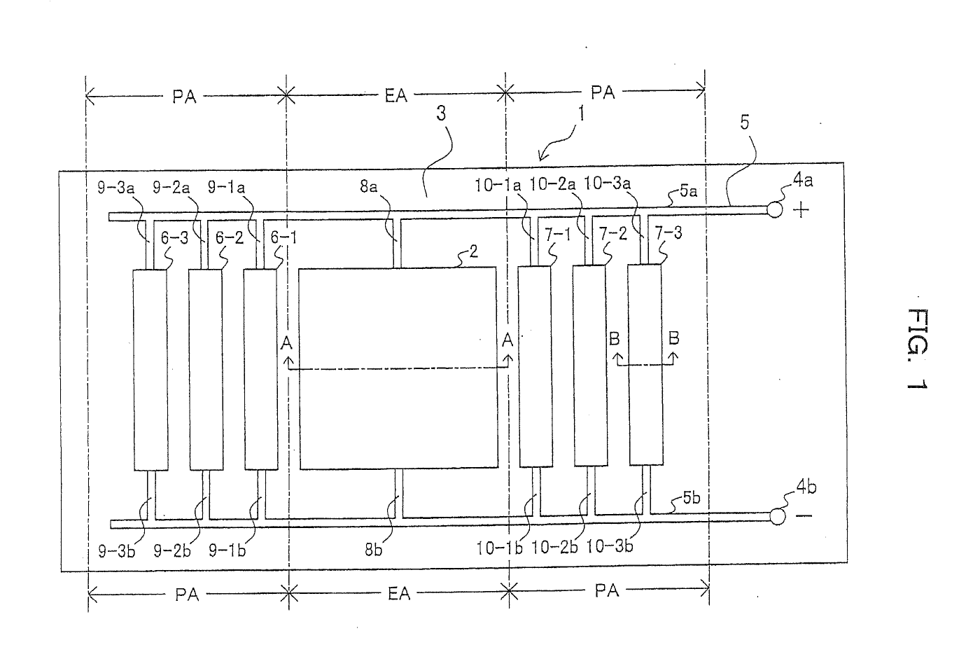

An organic EL panel according to an embodiment of the present invention and a method for manufacturing a light-emitting, i.e., illuminating device using the same will be described with reference to FIGS. 1 to 12.

As shown in FIG. 1, an organic EL panel 1 according to the present invention includes a transparent substrate 3 made of a generally rectangular transparent material such as a glass, for example, and carrying a light-emitting section 2 at a central portion thereof. External connecting terminals 4a and 4b, which are current supply terminals, are provided in the vicinity of one end of the substrate 3 in a longitudinal direction thereof, for example. Trunk portions 5a and 5b of a conductive pattern 5 provided on the substrate 3 are connected to the external connecting terminals 4a and 4b, respectively. The trunk portions 5a and 5b extend along edges of the substrate 3 in parallel to each other at positions interposing the light-emitting section 2 therebetween.

Current density adjusting sections 6-1, 6-2, 6-3, 7-1, 7-2, and 7-3 are provided between the trunk portions 5a and 5b and at both sides of the light-emitting section 2 on the substrate 3. The trunk portions 5a and 5b and an anode and a cathode of the light-emitting section 2 are connected to each other via branch portions 8a and 8b of the conductive pattern 5, respectively.

An embodiment when the current density adjusting sections 6-1 to 6-3 and 7-1 to 7-3 have the same layer structure as the light-emitting section 2 will be illustrated below.

Branch portions 9-1a, 9-1b, 9-2a, 9-2b, 9-3a, 9-3b, 10-a, 10-b, 10-a, 10-b, 10-a, and 10-b are extended from the trunk portions 5a and 5b and connected to anodes and cathodes of the current density adjusting sections 6-1, 6-2, 6-3, 7-1, 7-2, and 7-3.

The branch portions 9-1a, 9-2a, 9-3a, 10-a, 10-2a, and 10-a of the conductive pattern 5 connect between the trunk portion 5a and the anodes of the current density adjusting sections 6-1, 6-2, 6-3, 7-1, 7-2, and 7-3. The branch portions 9-1b, 9-2b, 9-3b, 10-b, 10-b, and 10-b of the conductive pattern 5 connect between the trunk portion 5b and the cathodes of the current density adjusting sections 6-1, 6-2, 6-3, 7-1, 7-2, and 7-3.

From the perspective of the external connecting terminals 4a and 4b (4a is set as a positive side and 4b is set as a negative side, for example) in the organic EL panel 1, the conductive pattern 5 electrically connects the light-emitting section 2 and the current density adjusting sections 6-1, 6-2, 6-3, 7-1, 7-2, and 7-3 in parallel to one another with the trunk portions 5a and 5b and the branch portions 8a, 8b, 9-1a, 9-1b, 9-2a, 9-2b, 9-3a, 9-3b, 10-a, 10-b, 10-a, 10-b, 10-a, and 10-b so as to form a parallel circuit.

An occupied area of the light-emitting section 2 on the substrate 3 is larger than any one of occupied areas of the current density adjusting sections 6-1 to 6-3 and 7-1 to 7-3.

The current density adjusting sections 6-1 to 6-3 are disposed on the substrate 3 on one of lateral sides of the light-emitting section 2 so as to be separated from one another. The current density adjusting sections 7-1 to 7-3 are disposed on the other one of the lateral sides of the light-emitting section 2 so as to be separated from one another.

In the embodiment shown in FIG. 1, the three current density adjusting sections 6-1 to 6-3 and 7-1 to 7-3 are disposed at the sides of the light-emitting section 2, respectively. However, the number of the current density adjusting sections 6-1 to 6-3 and 7-1 to 7-3 is not limited thereto.

The current density adjusting sections 6-1 to 6-3 and 7-1 to 7-3 may have areas identical to or different from one another. When those areas are different from one another, a difference between such areas may be set at a fixed value or may have a certain multiplying factor or a power of 2. Each area of the current density adjusting sections 6-1 to 6-3 and 7-1 to 7-3 may be set at a known value in advance.

Note that an easily-disconnectable portion at which disconnection from the other portions on the substrate 3 can be easily performed by a disconnection means, i.e., an easily-disconnectable part (not shown) is preferably provided in a region including the branch portions 9-1a, 9-1b, 9-2a, 9-2b, 9-3a, 9-3b, 10-a, 10-b, 10-a, 10-b, 10-a, and 10-b and the current density adjusting sections 6-1 to 6-3 and 7-1 to 7-3.

In order to indicate the position of the easily-disconnectable portion, it is further preferable that a mark or the like with which the easily-disconnectable portion can be visually recognized or detected be provided on the substrate 3 or in the vicinity thereof. While a laser or the like, for example, is used as the disconnection means, a mechanical, electromagnetic, or optical method may be employed.

Accordingly, the current density adjusting sections 6-1 to 6-3 and 7-1 to 7-3 can be easily separated one by one from the parallel circuit in the organic EL panel 1 by means of disconnection at the corresponding easily-disconnectable portions. The organic EL panel 1 of the present embodiment can adjust the current density of the light-emitting section as desired by separating any one of the current density adjusting sections 6-1 to 6-3 and 7-1 to 7-3.

Furthermore, the shape of the substrate 3 is not limited to a rectangular shape. The substrate 3 may have a square shape. Alternatively, the substrate 3 may have a circular or oval shape. In short, it is only necessary that the current density adjusting sections are disposed at the sides of the light-emitting section 2. Moreover, the conductive pattern 5 may have any pattern shape as long as current paths including the current density adjusting sections are connected in parallel to the light-emitting section 2 and a current flowing through the light-emitting section 2 can be changed as desired by disconnecting at least one portion of the conductive pattern 5.

It is apparent here that an effective light-emitting region EA, which includes the light-emitting section 2 and is therefore effective as a light-emitting region, is provided in the organic EL panel 1 according to the present invention and post-processing regions PA capable of post-processing are provided at the sides of the effective light-emitting region EA.

A voltage-current characteristic, i.e., a current density of the organic EL panel 1 can be adjusted by disconnecting part of the conductive pattern 5 by means of laser processing, peeling off the cathode in a part of the current density adjusting sections, or cutting the substrate 3 in the post-processing region PA.

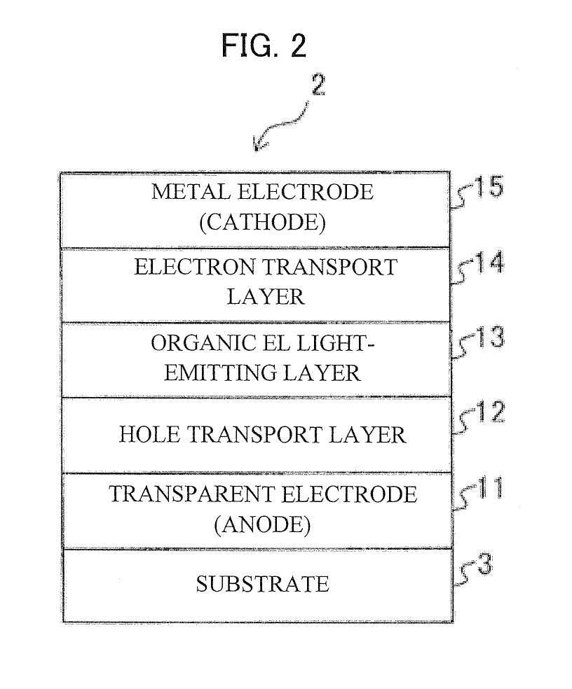

As shown in FIG. 2, the light-emitting section 2 includes a transparent electrode 11 serving as an anode, for example, and layered on the substrate 3. A hole transport layer 12 is layered on the transparent electrode 11, an organic EL light-emitting layer 13 is layered on the hole transport layer 12, an electron transport layer 14 is layered on the organic EL light-emitting layer 13, and a metal electrode 15 serving as a cathode is layered on the electron transport layer 14.

As is well known, indium tin oxide (ITO) may be used as a material of the anode and aluminum (Al) may be used as a material of the cathode in the light-emitting section 2.

In the illustrated light-emitting section 2, the structure of an organic functional layer made of the hole transport layer 12, the organic EL light-emitting layer 13, and the electron transport layer 14 layered one another between the transparent electrode 11 and the metal electrode 15 is of a three-layer structure. Such an organic functional layer, however, may take various different structures (not shown) such as a single layer structure of the organic EL light-emitting layer 13, a two-layer structure made of the hole transport layer 12 and the organic EL light-emitting layer 13, or a five-layer structure made of a hole injection layer, the hole transport layer 12, the organic EL light-emitting layer 13, the electron transport layer 14, and an electron injection layer, for example.

Alternatively, the light-emitting section 2 may take a structure such that a large number of stripe-shaped organic EL laminates of R (red), G (green), and B (blue) as disclosed in Japanese Patent Application Laid-Open No. 2007-42658, for example, are juxtaposed to one another in the order of R, G, and B (not shown).

When the light-emitting section 2 has the structure in which the R, G, and B striped organic EL laminates are juxtaposed to one another, the current density adjusting sections 6-1 to 6-3 and 7-1 to 7-3 also need to have a striped structure corresponding to the respective groups of R, G, and B (not shown).

The current density adjusting sections 6-1 to 6-3 and 7-1 to 7-3 have the same layer structure as the light-emitting section 2. Thus, the current density adjusting sections 6-1 to 6-3 and 7-1 to 7-3 can be formed by the same process as the light-emitting section 2.

A case where the current density adjusting sections 6-1 to 6-3 and 7-1 to 7-3 are resistors is illustrated as another embodiment.

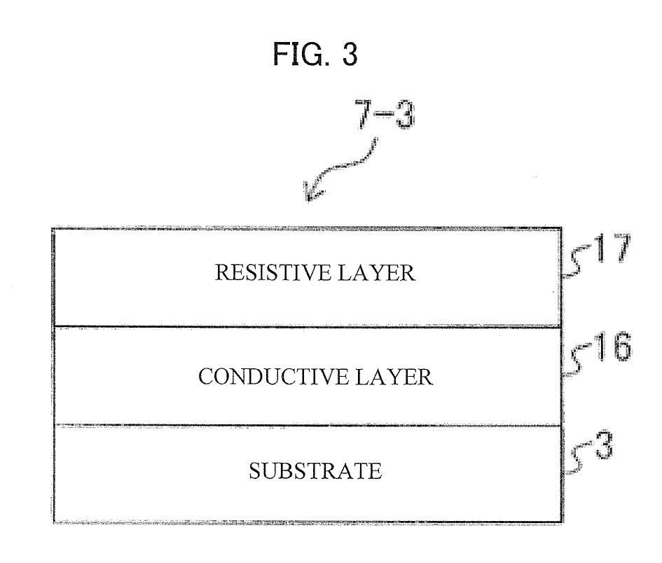

As shown in FIG. 3, each of the current density adjusting sections 6-1 to 6-3 and 7-1 to 7-3 is a layered resistor made of a conductive layer 16 formed on the substrate 3 and a resistive layer 17 layered on the conductive layer 16. Alternatively, each of the current density adjusting sections 6-1 to 6-3 and 7-1 to 7-3 may be a resistor having a single layer structure of the conductive layer 16.

A known conductive material such as Al, Cr, or ITO may be used as a material of the conductive layer 16. Al or Cr, for example, may be used as a material of the resistive layer 17. A material having a desired resistive characteristic can be used.

Moreover, both or either one of the conductive layer 16 and the resistive layer 17 may have the same material as one layer in the light-emitting section 2. In this case, particularly when the conductive layer 16 has the same material as the transparent electrode 11 serving as an anode and the resistive layer 17 has the same material as the metal electrode 15 serving as a cathode, the conductive layer 16 and the resistive layer 17 can be formed in the course of the manufacturing process of the light-emitting section 2.

The current density adjusting sections 6-1 to 6-3 and 7-1 to 7-3 may have the same or different resistance values. When those resistance values are different from one another, a difference between such resistance values may be set at a fixed value or may have a certain multiplying factor or a power of 2. Each resistance value of the current density adjusting sections 6-1 to 6-3 and 7-1 to 7-3 may be set at a known value in advance.

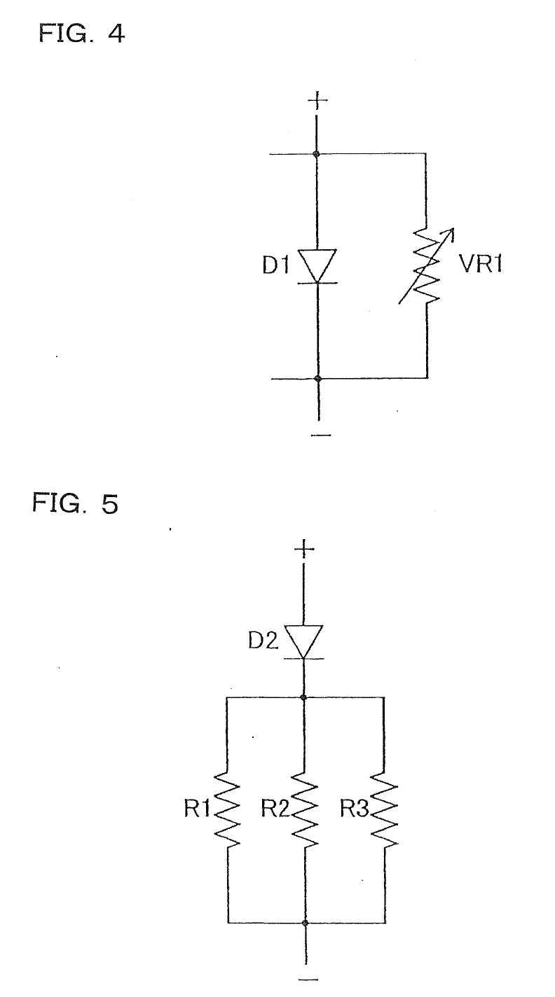

Furthermore, the current density adjusting sections 6-1 to 6-3 and 7-1 to 7-3 may include a chip component 18 such as a chip resistor. Alternatively, the current density adjusting sections 6-1 to 6-3 and 7-1 to 7-3 each may be an IC chip of a parallel circuit of a diode D1 and a variable resistor VR1 as shown in FIG. 4, for example. The variable resistor VR1 in FIG. 4 may be replaced by a semi-fixed resistor.

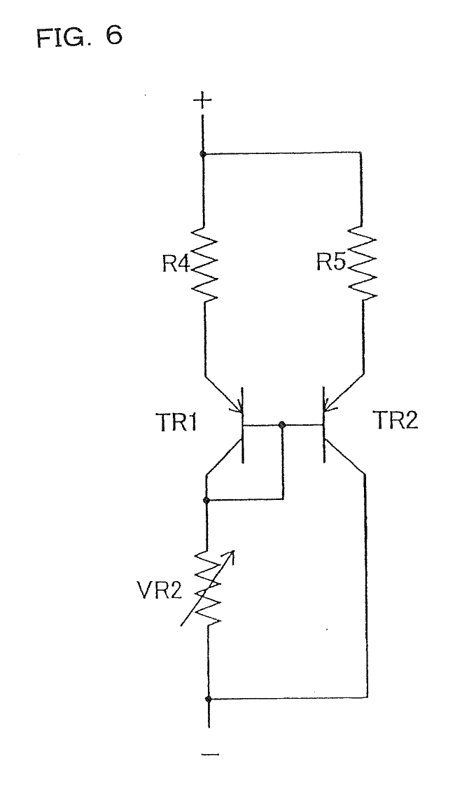

Such an IC chip may be an IC chip of a series circuit of a diode D2 and resistors R1, R2, and R3 connected in parallel as shown in FIG. 5. An IC chip of a current mirror circuit as shown in FIG. 6 may be used instead.

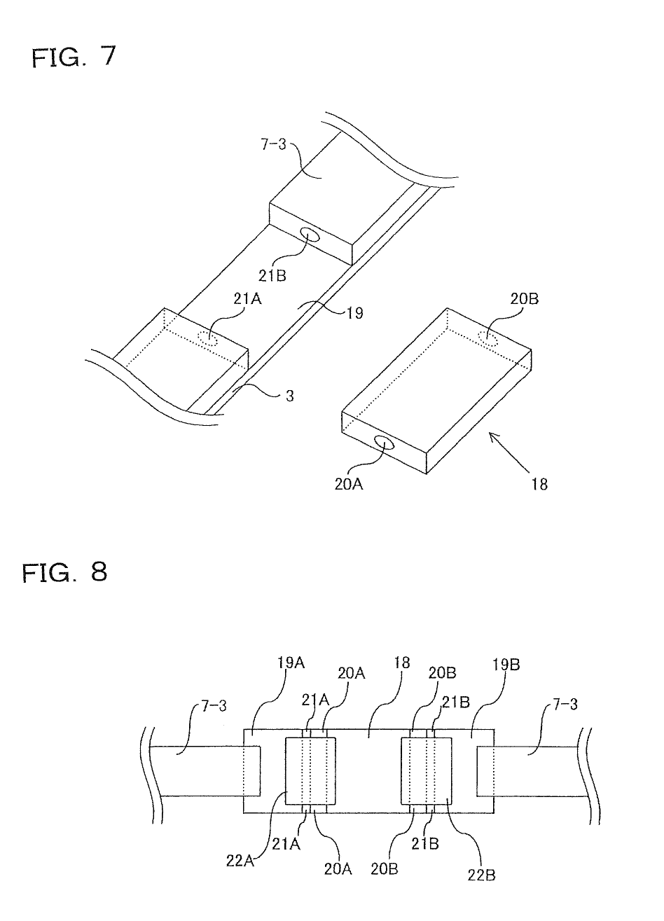

FIG. 7 shows a case where the current density adjusting sections 6-1 to 6-3 and 7-1 to 7-3 include the chip component 18. The current density adjusting sections 6-1 to 6-3 and 7-1 to 7-3 include a chip component mounting part 19 on which the chip component 18 can be mounted. The chip component 18 has a shape embedding an IC chip (not shown) therein by means of a resin material. The chip component 18 has a positive terminal 20A at one end thereof and a negative terminal 20B at the other end thereof. Moreover, the chip component mounting part 19 has a positive terminal 21A and a negative terminal 21B corresponding to the positive terminal 20A and the negative terminal 20B of the chip component 18, respectively.

As a result of the attachment of the chip component 18 to the chip component mounting part 19, the positive terminal 20A is connected to the positive terminal 21A and the negative terminal 20B is connected to the negative terminal 21B, thereby allowing a current to be supplied to the chip component 18 via the branch portions. When the current density adjusting sections 6-1 to 6-3 and 7-1 to 7-3 are resistors, the current density adjusting sections 6-1 to 6-3 and 7-1 to 7-3 may be disposed on the outside of a sealing part (not shown) for keeping the light-emitting element away from moisture or the like. When the current density adjusting sections 6-1 to 6-3 and 7-1 to 7-3 include the chip component mounting part 19, in accordance with the electrical characteristic of the organic EL panel 1, the chip component 18 mounted on the chip component mounting part 19 can be replaced afterward by another chip component 18 having a different resistance value and an optimal electrical characteristic.

Alternatively, the electrical characteristic of the organic EL panel 1 may be measured before the chip component 18 is mounted on the chip component mounting part 19 and the chip component 18 optimal for obtaining a desired electrical characteristic may be mounted on the basis of the measured result.

Note that it is only necessary that the chip component mounting part 19 on which the chip component 18 can be mounted is provided in at least a part of each of current density adjusting sections 6-1 to 6-3 and 7-1 to 7-3. Furthermore, the chip components 18 to be mounted on the chip component mounting parts 19 may be the same kind of IC chips or different kinds of IC chips in the current density adjusting sections 6-1 to 6-3 and 7-1 to 7-3. The shape of the terminal portions thereof is not limited to the illustrated shape and may take various shapes capable of connecting the chip component 18 and the chip component mounting part 19 together.

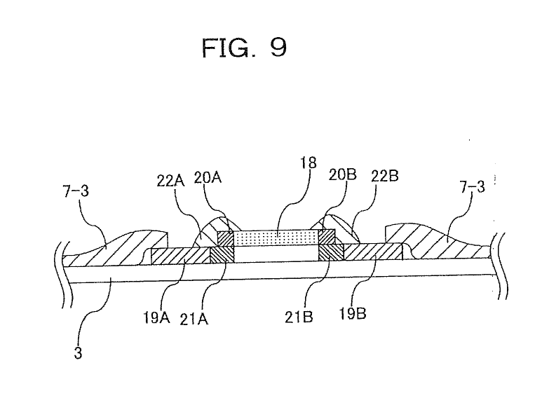

FIGS. 8 and 9 show another embodiment of the chip component mounting part 19. The current density adjusting sections 6-1 to 6-3 and 7-1 to 7-3 include the chip component 18, chip component mounting parts 19A and 19B, and joint parts 22A and 22B.

The chip component mounting part 19A has the positive terminal 21A and the chip component mounting part 19B has the negative terminal 21B. The chip component mounting parts 19A and 19B are formed on the substrate 3 and made of a metal such as Al, for example, and disposed so as to be spaced apart from each other. The chip component 18 has the positive terminal 20A and the negative terminal 20B corresponding to the positive terminal 21A and the negative terminal 21B, respectively. The chip component 18 is disposed on the chip mounting parts 19A and 19B. Consequently, the positive terminal 20A and the positive terminal 21A are connected to each other and the negative terminal 20B and the negative terminal 21B are connected to each other, thereby allowing a current to be supplied to the chip component 18 via the branch portions.

The joint parts 22A and 22B are made of a solder or a silver paste, for example, and join the positive terminal 20A with the positive terminal 21A and join the negative terminal 20B with the negative terminal 21B, respectively. Moreover, the chip component 18, the chip component mounting parts 19A and 19B, and the joint parts 22A and 22B may be covered with a resin material, for example, and the resin material may be shaped and cured.

A part of each of current density adjusting sections 6-1 to 6-3 and 7-1 to 7-3 is layered on a part of the chip component mounting part 19. Consequently, the adhesion of the chip component mounting part 19 is enhanced, thereby making the chip component mounting part 19 less likely to be peeled off from the substrate 3.

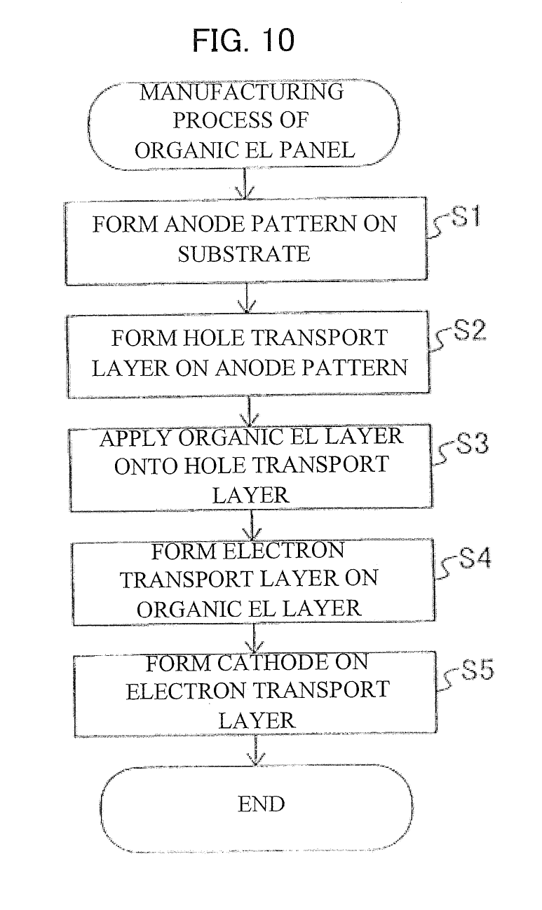

A manufacturing process of the organic EL panel 1 will be described with reference to FIG. 10.

First, the substrate 3 made of a transparent material such as a glass or a plastic is prepared. The transparent electrode 11 as an anode pattern is then formed on the substrate 3 (step S1). A conductive material having a large work function, for example, indium tin oxide (ITO) with a thickness of about 1000 to 3000 angstroms or gold with a thickness of about 800 to 1500 angstroms may be used as the anode.

Specifically, a film is deposited on the substrate 3 by a vapor deposition method or a sputtering method, for example, and an anode pattern is patterned by photolithography.

After the step S1, the hole transport layer 12 is formed on the anode pattern made of the transparent electrode 11 (step S2). The organic EL light-emitting layer 13 is applied onto the hole transport layer 12 formed in the step S2 (step S3). The electron transport layer 14 is formed on the organic EL light-emitting layer 13 applied in the step S3 (step S4).

Next, the metal electrode 15, which is a cathode, is formed on the electron transport layer 14 (step S5). A metal having a small work function, for example, aluminum, magnesium, indium, silver, or an alloy thereof with a thickness of about 100 to 5000 angstroms may be used for the metal electrode 15 as a cathode.

The external connecting terminals 4a and 4b and the conductive pattern 5 are formed on the substrate 3 by a known technique.

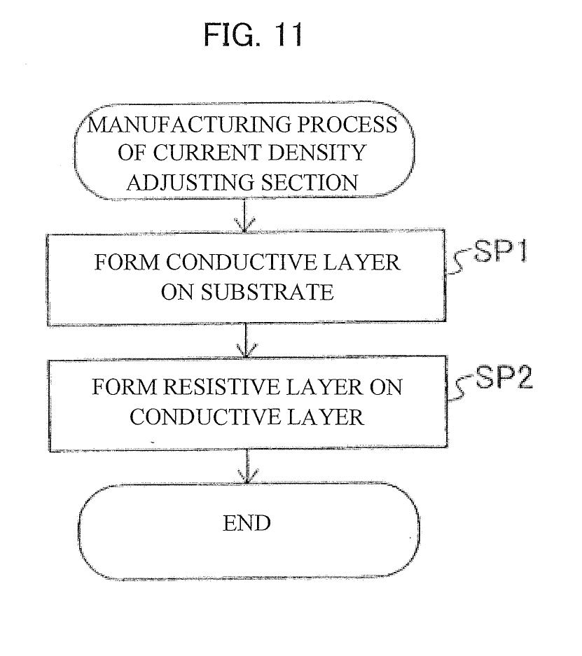

A manufacturing process of the current density adjusting sections 6-1 to 6-3 and 7-1 to 7-3 will be described with reference to FIG. 11.

When the current density adjusting sections 6-1 to 6-3 and 7-1 to 7-3 have the same layer structure as the light-emitting section 2, the formation of the current density adjusting sections 6-1 to 6-3 and 7-1 to 7-3 can be performed simultaneously with the manufacturing process of the organic EL panel 1 shown in FIG. 10. When the current density adjusting sections 6-1 to 6-3 and 7-1 to 7-3 are resistors, the conductive layer 16 is first formed on the substrate 3 prepared in the step S1 in the manufacturing process of the organic EL panel 1 (step SP1). A method for forming the conductive layer 16 is formation by a known technique. When the conductive layer 16 of the current density adjusting sections 6-1 to 6-3 and 7-1 to 7-3 has the same material as the transparent electrode 11 of the light-emitting section 2, the formation of the conductive layer 16 can be performed simultaneously with the step S1 in the manufacturing process of the organic EL panel 1. When each of the current density adjusting sections 6-1 to 6-3 and 7-1 to 7-3 is a resistor with a single layer structure of the conductive layer 16, this manufacturing process is ended.

When each of the current density adjusting sections 6-1 to 6-3 and 7-1 to 7-3 is a layered resistor of the conductive layer 16 and the resistive layer 17, the resistive layer 17 is formed on the conductive layer 16 formed in the step SP1 (step SP2). The resistive layer 17 is formed by a known technique. When the resistive layer 17 is the same as the metal electrode 15 of the light-emitting section 2, the formation of the resistive layer 17 can be performed simultaneously with the step S5 in the manufacturing process of the organic EL panel 1.

If the current density adjusting sections 6-1 to 6-3 and 7-1 to 7-3 as shown in FIGS. 7 to 9 include the chip component mounting part 19, the chip component mounting part 19 is formed and the positive terminal 21A and the negative terminal 21B corresponding to the positive terminal 20A and the negative terminal 20B of the chip component 18, respectively, are formed during the formation of the conductive layer 16 in the case of the single layer structure of the conductive layer 16. In the case of the two-layer structure of the conductive layer 16 and the resistive layer 17, the chip component mounting part 19 is formed and the positive terminal 21A and the negative terminal 21B corresponding to the positive terminal 20A and the negative terminal 20B of the chip component 18, respectively, are formed during the formation of the conductive layer 16 and the resistive layer 17.

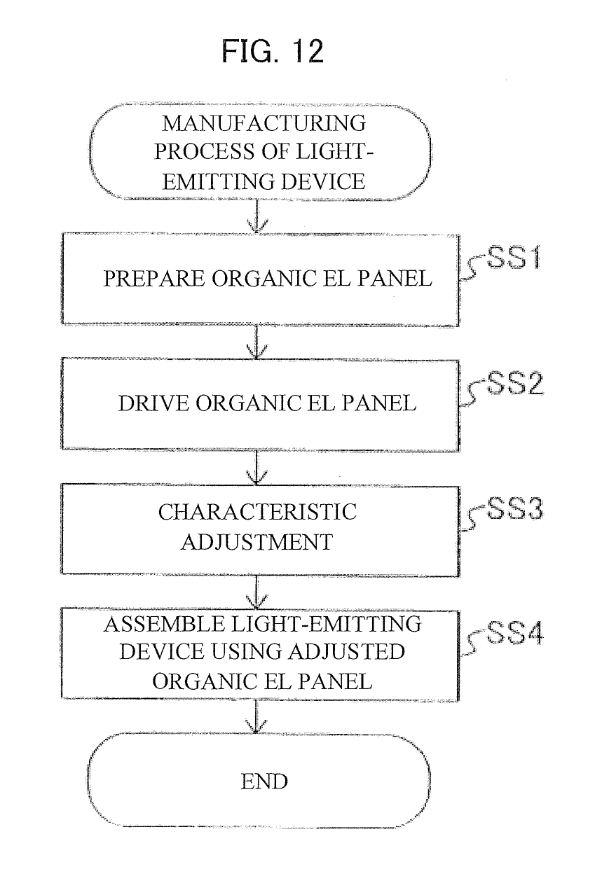

A method for manufacturing a light-emitting device will be described with reference to FIG. 12.

The organic EL panel 1 shown in FIG. 1 is prepared (step SS1).

After the step SS1, the organic EL panel 1 is driven (step SS2). More specifically, positive-side and negative-side terminals of a direct-current power source are connected to the external connecting terminals 4a and 4b of the organic EL panel 1 in this step. A direct-current power is supplied to the light-emitting section 2 and the current density adjusting sections 6-1 to 6-3 and 7-1 to 7-3 from the external connecting terminals 4a and 4b via the trunk portions 5a and 5b and the branch portions 8a, 8b, 9-1a, 9-1b, 9-2a, 9-2b, 9-3a, 9-3b, 10-a, 10-b, 10-a, 10-b, 10-a, and 10-b.

Next, the electrical characteristic and emission luminance of the organic EL panel 1 are adjusted (step SS3).

In this step, an electrical characteristic such as a voltage or a resistance between the external connecting terminals 4a and 4b of the organic EL panel 1 and the emission luminance of the light-emitting section 2 in the effective light-emitting region EA are measured. Then, an adjustment is made so as to obtain a desired electrical characteristic between the external connecting terminals 4a and 4b in order to obtain a desired emission luminance in the light-emitting section 2 in the effective light-emitting region EA. Note that only either one of the electrical characteristic such as a voltage or a resistance between the external connecting terminals 4a and 4b of the organic EL panel 1 and the emission luminance of the light-emitting section 2 in the effective light-emitting region EA may be measured.

In other words, the electrical characteristic can be adjusted between the external connecting terminals 4a and 4b. The number of the current density adjusting sections 6-1 to 6-3 and 7-1 to 7-3 included in the parallel circuit formed by the conductive pattern 5 can be adjusted by disconnecting a part of the conductive pattern in the organic EL panel 1 with a laser or the like. For example, the branch portion 9-3a connecting between the trunk portion 5a and the anode of the current density adjusting section 6-3 is disconnected, thereby separating the current density adjusting section 6-3 from the parallel circuit in the organic EL panel 1.

Consequently, the resistance value of the entire parallel circuit is increased and the voltage between the external connecting terminals 4a and 4b can be thereby adjusted. In other words, currents individually flowing to the light-emitting section 2 between the branch portions 8a and 8b can be adjusted.

If the current density adjusting section 6-3 is separated from the parallel circuit in the organic EL panel 1 and an adjustment to a desired electrical characteristic between the external connecting terminals 4a and 4b of the organic EL panel 1 is thereby successfully completed, the adjustment step SS3 for the electrical characteristic and emission luminance of the organic EL panel 1 is ended.

If an adjustment to a desired electrical characteristic between the external connecting terminals 4a and 4b of the organic EL panel 1 has failed, on the other hand, the branch portion 9-2a connecting between the trunk portion 5a and the anode of the current density adjusting section 6-2 is disconnected with a laser or the like, for example, thereby separating the current density adjusting section 6-2 from the parallel circuit in the organic EL panel 1. Note that the cathode in a part of the current density adjusting section may be peeled off or the branch portion 9-2b may be disconnected with a laser or the like in this disconnection step.

In this manner, a part of the conductive pattern (for example, any one or more of the branch portions 9-1a, 9-1b, 9-2a, 9-2b, 9-3a, 9-3b, 10-a, 10-b, 10-a, 10-b, 10-a, and 10-b) is disconnected with a laser or the like in accordance with a need to adjust the electrical characteristic of the parallel circuit in the organic EL panel 1, thereby separating any one or more of the current density adjusting sections 6-1 to 6-3 and 7-1 to 7-3 from the parallel circuit in the organic EL panel 1. The conductive pattern 5 including the branch portions 9-1a, 9-1b, 9-2a, 9-2b, 9-3a, 9-3b, 10-a, 10-b, 10-a, 10-b, 10-3a, and 10-b is made of a metal which is a known conductive material and can be easily disconnected with a laser or the like.

Although the branch portion 9-3a connecting between the trunk portion 5a and the anode of the current density adjusting section 6-3, for example, is disconnected with a laser in the present embodiment, the branch portion 9-3b connecting between the trunk portion 5b and the cathode of the current density adjusting section 6-3 may be disconnected instead.

When the current density adjusting sections 6-1 to 6-3 and 7-1 to 7-3 have the same layer structure as the light-emitting section 2, the current density adjusting sections 6-1 to 6-3 and 7-1 to 7-3 also emit light. If such light emission interferes with the measurement of the emission luminance of the light-emitting section 2, the light-emitting portions of the current density adjusting sections 6-1 to 6-3 and 7-1 to 7-3 may be covered by applying a masking, a cover, or the like, to the current density adjusting sections 6-1 to 6-3 and 7-1 to 7-3.

When the current density adjusting sections 6-1 to 6-3 and 7-1 to 7-3 include the chip component mounting part 19, an electrical characteristic such as a voltage or a resistance between the external connecting terminals 4a and 4b of the organic EL panel 1 and the emission luminance of the light-emitting section 2 in the effective light-emitting region EA are measured in the present step. Then, an adjustment may be made so as to obtain a desired electrical characteristic between the external connecting terminals 4a and 4b by performing a replacement by the chip component 18 optimal for obtaining a desired emission luminance in the light-emitting section 2 in the effective light-emitting region EA afterward.

Alternatively, in the present step, an electrical characteristic such as a voltage or a resistance between the external connecting terminals 4a and 4b of the organic EL panel 1 and the emission luminance of the light-emitting section 2 in the effective light-emitting region EA may be measured before the chip component 18 is mounted on the chip component mounting part 19 and the chip component 18 optimal for obtaining a desired electrical characteristic between the external connecting terminals 4a and 4b may be mounted on the basis of the measured results of such measurements.

Note that only either one of the electrical characteristic such as a voltage or a resistance between the external connecting terminals 4a and 4b of the organic EL panel 1 and the emission luminance of the light-emitting section 2 in the effective light-emitting region EA may be measured.

Next, the light-emitting device using the organic EL panel 1 having completed the adjustment of the electrical characteristic and the emission luminance is assembled (step SS4). For example, the organic EL panel 1 with the adjusted emission luminance is subjected to other required inspections and processing such as burring or washing and the assembly of the light-emitting device using the organic EL panel 1 is performed.

Note that the light-emitting section 2 in the effective light-emitting region EA and the current density adjusting sections 6-1 to 6-3 and 7-1 to 7-3 are different from each other as laminates in terms of the outer shapes and layered structures thereof in the above-described embodiment. According to the present invention, however, the laminate structure in the light-emitting section 2 may be replaced by a juxtaposed structure of a group of stripe-shaped organic EL laminates and each of the current density adjusting sections 6-1 to 6-3 and 7-1 to 7-3 may also be replaced by a juxtaposed structure of a group of stripe-shaped organic EL laminates, for example, and the light-emitting section 2 and the current density adjusting sections 6-1 to 6-3 and 7-1 to 7-3 can be formed concurrently by a series of processes.

In such a case, the position of a boundary between the effective light-emitting region EA and the post-processing region PA in the longitudinal direction of the substrate 3 can be selected. This is because the organic EL panel 1 according to the present invention can be housed in a case (not shown) having a transparent window with a shape in accordance with a predetermined standard, for example, and commercialized as a light-emitting, i.e., illuminating device.

Note that when the current density adjusting sections 6-1 to 6-3 and 7-1 to 7-3 have the same layer structure as the light-emitting section 2, the current density adjusting sections 6-1 to 6-3 and 7-1 to 7-3 may be provided in the effective light-emitting region EA.

Furthermore, although the description of the embodiments of the present invention has been made on the basis of the premise that the external connecting terminals 4a and 4b correspond to a positive side and a negative side, respectively, the present invention is not limited to such a case. The external connecting terminals 4a and 4b may correspond to a negative side and a positive side, respectively.

### REFERENCE SIGNS LIST

1 organic EL panel
2 light-emitting section
3 substrate
4a, 4b external connecting terminal
5 conductive pattern
5a, 5b trunk portion
6-1 to 6-3, 7-1 to 7-3 current density adjusting section
8a, 8b, 9-1a to 9-3a, 9-1b to 9-3b, 10-1a to 10-a, 10-1b to 10-b branch portion
11 transparent electrode (anode)
12 hole transport layer
13 organic EL light-emitting layer
14 electron transport layer
15 metal electrode (cathode)
16 conductive layer
17 resistive layer
18 chip component
19 chip component mounting section
20A positive terminal
20B negative terminal
21A positive terminal
21B negative terminal
22A, 22B joint part
EA effective light-emitting region
PA post-processing region

1. An organic EL panel comprising: a substrate; a light-emitting section of the organic EL panel provided on the substrate; a current supply terminal provided on the substrate for supplying a current to the light-emitting section; and a current density adjusting section electrically connected to the current supply terminal in parallel to the light-emitting section and provided on the substrate, wherein a current density of the light-emitting section is adjusted by processing the current density adjusting section.

2. The organic EL panel according to claim 1, wherein the current density adjusting section includes an easily-disconnectable part and the processing of the current density adjusting section is performed by disconnecting the easily-disconnectable part by a mechanical, electromagnetic, or optical breakage method.

3. The organic EL panel according to claim 2, wherein the current density adjusting section is formed by a process same as that of the light-emitting section.

4. The organic EL panel according to claim 2, wherein the current density adjusting section is formed by a resistor.

5. The organic EL panel according to claim 2, wherein the current density adjusting section is provided in an effective light-emitting region.

6. The organic EL panel according to claim 1, wherein the current density adjusting section includes a chip component mounting part on which a chip component can be mounted.

7. A method for manufacturing an organic EL light-emitting device, the method comprising:
a measurement step of measuring an electrical characteristic via the current supply terminal of the organic EL panel according to claim 1;
a disconnection step of selectively disconnecting a part of an individual current path to the current density adjusting section of the organic EL panel on the basis of a measured result in the measurement step; and
a step of forming a light-emitting device including the organic EL panel having undergone the disconnection step.

8. The method according to claim 7, wherein the measurement step includes a luminance measurement step of measuring an emission luminance of the light-emitting section of the organic EL panel.

9. A method for manufacturing an organic EL light-emitting device, the method comprising:
a measurement step of measuring an electrical characteristic via the current supply terminal of the organic EL panel according to claim 6;
a mounting step of mounting a chip component on the chip component mounting part of the organic EL panel based on a measured result in the measurement step; and
forming a light-emitting device including the organic EL panel having undergone the mounting step.
